(19) United States
(12) Patent Application Publication
(10) Pub. No.: US 2025/0329586 A1
(43) Pub. Date: Oct. 23, 2025

(54) SEMICONDUCTOR STRUCTURE AND METHOD OF FORMING THE SAME

(71) Applicant: NANYA TECHNOLOGY CORPORATION, New Taipei city (TW)

(72) Inventor: Yu-Tang CHEN, New Taipei City (TW)

(21) Appl. No.: 18/642,232

(22) Filed: Apr. 22, 2024

(51) Int. Cl. H01L 21/768; H01L 23/522; H01L 23/532

(52) U.S. Cl. CPC H01L 21/76877; H01L 21/76805; H01L 21/76843; H01L 23/5226; H01L 23/53223; H01L 23/53228

(57) ABSTRACT

A semiconductor structure includes a first dielectric layer, a protection layer, a second dielectric layer, a first buffer layer, and a second metal line. The first dielectric layer has a first metal line in a top surface of the first dielectric layer. The protection layer is located on the first dielectric layer. The second dielectric layer is located on the protection layer, wherein the second dielectric layer and the protection layer have a through hole, and the first metal line is below the through hole. The first buffer layer is located on a top surface of the second dielectric layer, a sidewall of the through hole, and a top surface of the first metal line. The second metal line is located on the first buffer layer and extends into the through hole.

### BACKGROUND

### Field of Invention

The present disclosure relates to a semiconductor structure and a method of forming the semiconductor structure.

### Description of Related Art

With the development of modern technology, integration circuits and electrical products have been pushed for size reductions to match the trend of high integration and high density. The manufacturing and integration of semiconductor devices involve many complicated steps and operations. Integration in semiconductor devices becomes increasingly complicated. An increase in complexity of manufacturing and integration of the semiconductor device may cause deficiencies, and the fabrication cost and time may be increased due to additional process steps. Accordingly, there is a continuous need to improve the manufacturing process of semiconductor devices so that the problems can be overcome.

In conventional BEOL (Back end of line) manufacturing process, an upper dielectric layer is etched to form a through hole to expose a copper line, and then the through hole is filled with tungsten material. Thereafter, an aluminum line is formed to cover the upper dielectric layer and the tungsten material. As a result, the tungsten material acts as a conductive via to electrically connect the upper metal line and the lower metal line. However, the formation of the conductive via includes many manufacturing steps, such as deposition and chemical mechanical polishing (CMP), to take a lot cycle time. Due to polishing the tungsten material, most of the tungsten material is wasted. In addition, the conductivity of the tungsten material is not good, and the resistance is increased in electrical performance, thereby decreasing the process window associated with chip size shrinkage.

### SUMMARY

According to some embodiments of the present disclosure, a semiconductor structure includes a first dielectric layer, a protection layer, a second dielectric layer, a first buffer layer, and a second metal line. The first dielectric layer has a first metal line in a top surface of the first dielectric layer. The protection layer is located on the first dielectric layer. The second dielectric layer is located on the protection layer, wherein the second dielectric layer and the protection layer have a through hole, and the first metal line is below the through hole. The first buffer layer is located on a top surface of the second dielectric layer, a sidewall of the through hole, and a top surface of the first metal line. The second metal line is located on the first buffer layer and extends into the through hole.

In some embodiments, the second metal line has a bottom portion surrounded by the second dielectric layer and the protection layer.

In some embodiments, the second metal line is integrally formed so as to have no interface therein.

In some embodiments, a material of the second metal line is different from a material of the first metal line.

In some embodiments, a material of the second metal line comprises aluminum, and a thickness of the second metal line above the first buffer layer is in a range from 700 nm to 800 nm.

In some embodiments, a material of the first buffer layer comprises titanium nitride.

In some embodiments, the semiconductor structure further includes a second buffer layer located on a top surface of the second metal line.

In some embodiments, a material of the second buffer layer is the same as a material of the first buffer layer.

In some embodiments, the semiconductor structure further includes a third dielectric layer located on the second buffer layer.

In some embodiments, the third dielectric layer, the second buffer layer, the second metal line, the first buffer layer, and a top portion of the second dielectric layer have a through hole.

According to some embodiments of the present disclosure, a method of forming a semiconductor structure includes forming a through hole to expose a first metal line in a top surface of a first dielectric layer, wherein the through hole is located in a second dielectric layer and a protection layer, and the protection layer is located on the first dielectric layer, and the second dielectric layer is located on the protection layer; forming a first buffer layer on a top surface of the second dielectric layer, a sidewall of the through hole, and a top surface of the first metal line; and forming a second metal line on the first buffer layer and extending into the through hole.

In some embodiments, the method of forming the semiconductor structure further includes forming a second buffer layer on a top surface of the second metal line.

In some embodiments, the first buffer layer, the second metal line, and the second buffer layer are formed by sputtering.

In some embodiments, the first buffer layer, the second metal line, and the second buffer layer are formed in the same chamber.

In some embodiments, the method of forming the semiconductor structure further includes forming a third dielectric layer on the second buffer layer.

In some embodiments, the method of forming the semiconductor structure further includes etching the third dielectric layer, the second buffer layer, the second metal line, the first buffer layer, and a top portion of the second dielectric layer to form a through hole.

In some embodiments, the method of forming the semiconductor structure further includes forming a photoresist layer on a top surface of the third dielectric layer, wherein the photoresist layer has an opening to expose a portion of a top surface of the third dielectric layer.

In some embodiments, the method of forming the semiconductor structure further includes forming the second buffer layer on the top surface of the second metal line is performed such that the second buffer layer is in contact with the top surface of the second metal line.

In some embodiments, forming the second metal line on the first buffer layer is performed such that the second metal line is in contact with the first buffer layer.

In some embodiments, forming the through hole to expose the first metal line includes forming a photoresist layer on the top surface of the second dielectric layer, wherein the photoresist layer has an opening to expose a portion of the top surface of the second dielectric layer; and etching the second dielectric layer and the protection layer that are below the opening of the photoresist layer.

In the aforementioned embodiments of the present disclosure, since the second metal line is located on the first buffer layer and extends into the through hole of the second dielectric layer and the protection layer, the second metal line not only serves as a conductive line but also serves as a conductive via in the through hole. As a result, conventional manufacturing steps including depositing a tungsten material and polishing the tungsten material to form a conductive via can be omitted to save the material cost and to improve the cycle time. Moreover, the second metal line is formed by one sputter step such that the entirety of the second metal line has the same material. Therefore, the conductivity of the second metal line in the through hole can be greater than that of the tungsten material, and thus the resistance is decreased in electrical performance, thereby increasing the process window associated with chip size shrinkage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor structure according to some embodiments of the present disclosure.

FIG. 2 is a flow chart of a method of forming a semiconductor structure according to some embodiments of the present disclosure.

FIGS. 3 to 9 are cross-sectional views at intermediate stages of a method of forming a semiconductor structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

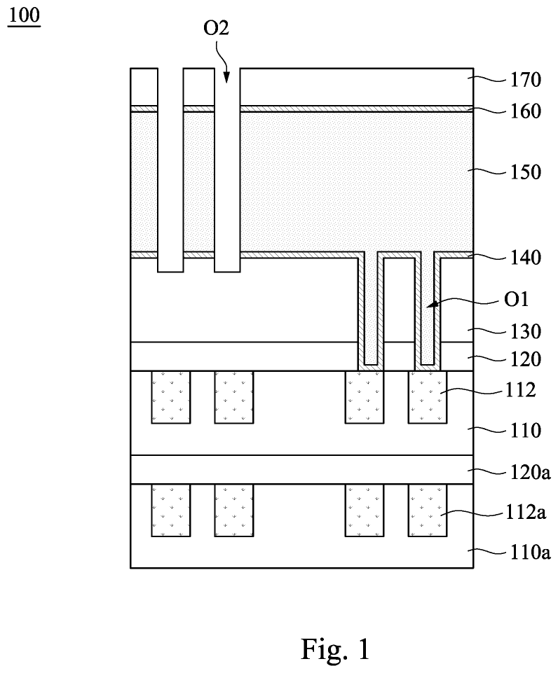

FIG. 1 is a cross-sectional view of a semiconductor structure 100 according to some embodiments of the present disclosure. As shown in FIG. 1, the semiconductor structure 100 includes a first dielectric layer 110, a protection layer 120, a second dielectric layer 130, a first buffer layer 140, and a second metal line 150. The first dielectric layer 110 has a first metal line 112 in the top surface of the first dielectric layer 110. The protection layer 120 is located on the first dielectric layer 110. The second dielectric layer 130 is located on the protection layer 120. Moreover, the second dielectric layer 130 and the protection layer 120 have a through hole O1, and the first metal line 112 is below the through hole O1. The first buffer layer 140 is located on the top surface of the second dielectric layer 130, the sidewall of the through hole O1, and the top surface of the first metal line 112. The sidewall of the through hole O1 includes the inner sidewall of the second dielectric layer 130 and the inner sidewall of the protection layer 120 surrounding the through hole O1. The second metal line 150 is located on the first buffer layer 140 and extends into the through hole O1. In other words, the second metal line 150 has a bottom portion surrounded by the second dielectric layer 130 and the protection layer 120. Furthermore, the second metal line 150 is integrally formed so as to have no interface therein.

In some embodiments, the semiconductor structure 100 may be formed on a semiconductor substrate (e.g., a silicon wafer) including devices. The semiconductor structure 100 may be a BEOL (Back end of line) structure in a memory device, and the bottom portion of the second metal line 150 in the protection layer 120 and the second dielectric layer 130 can serve as a conductive via. The material of the second metal line 150 is different from the material of the first metal line 112. For example, the material of the first metal line 112 may be copper (Cu), and the material of the second metal line 150 may be aluminum (Al). The thickness of the second metal line 150 above the first buffer layer 140 may be in a range from 700 nm to 800 nm. In addition, the first dielectric layer 110 and the second dielectric layer 130 may be oxide, and the protection layer 120 may be nitride or oxide.

Specifically, since the second metal line 150 is located on the first buffer layer 140 and extends into the through hole O1 of the second dielectric layer 130 and the protection layer 120, the second metal line 150 not only serves as a conductive line but also serves as a conductive via in the through hole O1. As a result, conventional manufacturing steps including depositing a tungsten material and polishing the tungsten material to form a conductive via can be omitted to save the material cost and to improve the cycle time. Moreover, the second metal line 150 is formed by one sputter step such that the entirety of the second metal line 150 has the same material (e.g., aluminum). Therefore, the conductivity of the second metal line 150 in the through hole O1 can be greater than that of the tungsten material, and thus the resistance is decreased in electrical performance, thereby increasing the process window associated with chip size shrinkage.

In some embodiments, the semiconductor structure 100 further includes a second buffer layer 160 and a third dielectric layer 170. The second buffer layer 160 is located on the top surface of the second metal line 150. The material of the second buffer layer 160 is the same as the material of the first buffer layer 140. For example, the material of each of the first and second buffer layers 140 and 160 may be titanium nitride (TIN). The third dielectric layer 170 is located on the second buffer layer 160. The third dielectric layer 170 may be an anti-reflection coating. For example, the material of the third dielectric layer 170 may be silicon oxynitride (SiON). The third dielectric layer 170, the second buffer layer 160, the second metal line 150, the first buffer layer 140, and a top portion of the second dielectric layer 130 have a through hole O2.

Furthermore, the semiconductor structure 100 may include another first dielectric layer 110a and a protection layer 120a below the first dielectric layer 110, and thus the protection layer 120a is located between the first dielectric layer 110 and the first dielectric layer 110a. The first dielectric layer 110a has a first metal line 112a therein.

It is to be noted that the connection relationships, the materials, and the advantages of the elements described above will not be repeated in the following description. In the following description, the method of forming the semiconductor structure 100 of FIG. 1 will be explained.

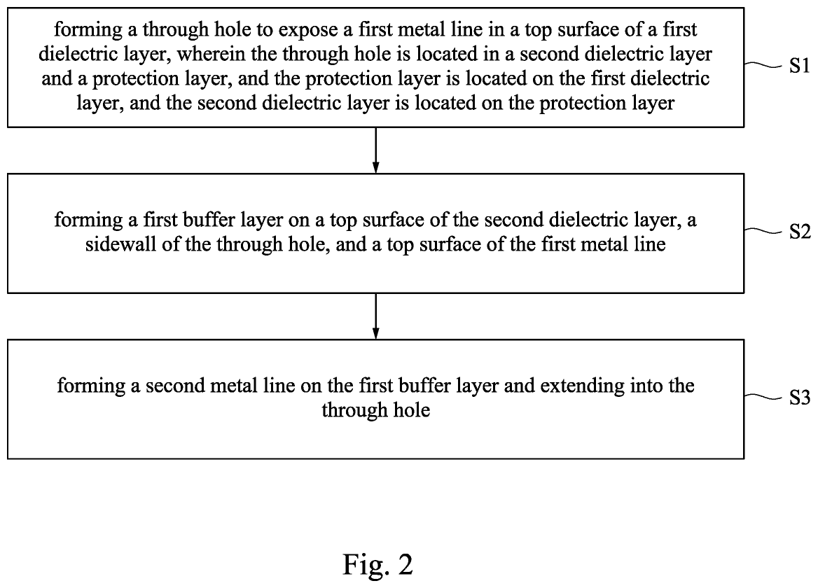

FIG. 2 is a flow chart of a method of forming a semiconductor structure according to some embodiments of the present disclosure. The method of forming the semiconductor structure includes the following steps. In step S1, a through hole is formed to expose a first metal line in a top surface of a first dielectric layer, wherein the through hole is located in a second dielectric layer and a protection layer, and the protection layer is located on the first dielectric layer, and the second dielectric layer is located on the protection layer. Thereafter, in step S2, a first buffer layer is formed on a top surface of the second dielectric layer, a sidewall of the through hole, and a top surface of the first metal line. Subsequently, in step S3, a second metal line is formed on the first buffer layer and extending into the through hole.

Moreover, each of steps S1 to S3 may include plural detailed steps, the method may include other steps between step S1 and step S3, and the method may include other steps before step S1 and after step S3. In the following description, at least the aforementioned steps S1 to S3 will be described in detail.

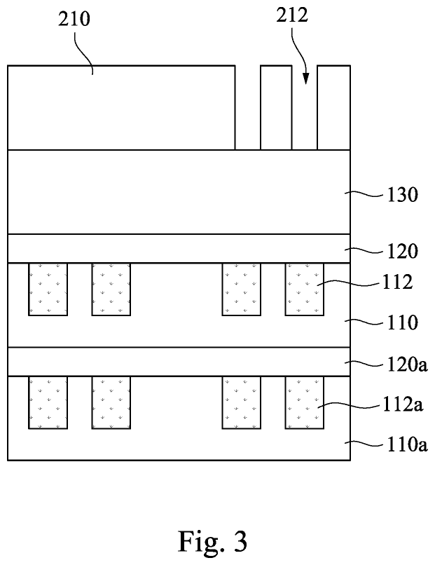

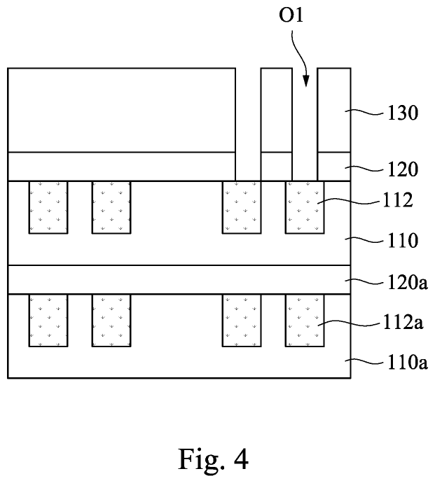

FIGS. 3 to 9 are cross-sectional views at intermediate stages of a method of forming a semiconductor structure according to some embodiments of the present disclosure. Referring to FIG. 3 and FIG. 4, the protection layer 120 is located on the first dielectric layer 110, and the second dielectric layer 130 is located on the protection layer 120. A photoresist layer 210 is formed on the top surface of the second dielectric layer 130, wherein the photoresist layer 210 is pattered to have an opening 212 to expose a portion of the top surface of the second dielectric layer 130. Thereafter, the second dielectric layer 130 and the protection layer 120 below the opening 212 of the photoresist layer 210 are etched. As a result, the through hole O1 is formed to expose the first metal line 112 in the top surface of the first dielectric layer 110. The through hole O1 is located in the second dielectric layer 130 and the protection layer 120.

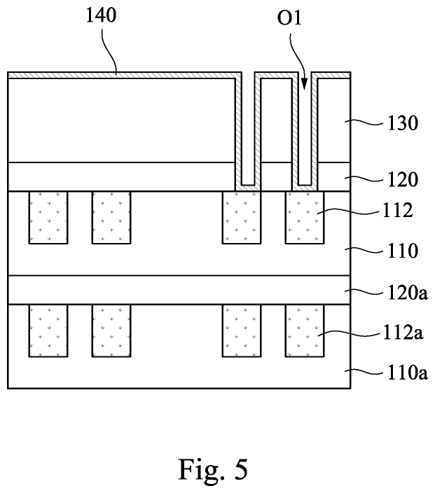

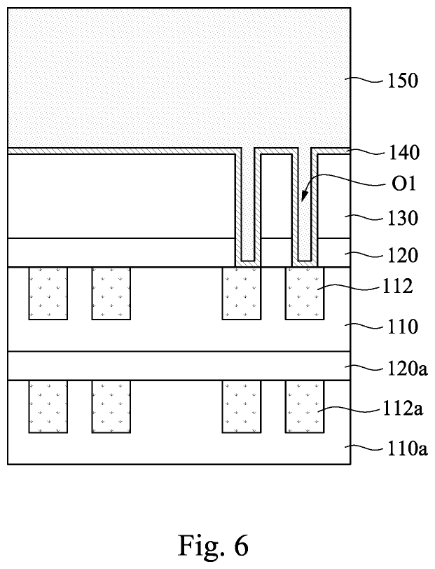

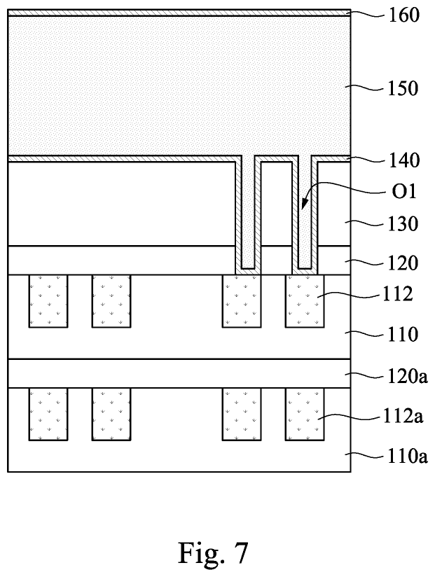

Referring to FIG. 5, after the formation of the through hole O1, the first buffer layer 140 is formed on the top surface of the second dielectric layer 130, the sidewall of the through hole O1, and the top surface of the first metal line 112. The material of the first buffer layer 140 may be titanium nitride (TiN). Referring to FIGS. 6 and 7, the second metal line 150 is formed on the first buffer layer 140 and extends into the through hole O1, and then the second buffer layer 160 is formed on the top surface of the second metal line 150. The material of the second metal line 150 may be aluminum (Al). The material of the second buffer layer 160 may be titanium nitride (TiN). In some embodiments, the first buffer layer 140, the second metal line 150, and the second buffer layer 160 are formed by sputtering, and the first buffer layer 140, the second metal line 150, and the second buffer layer 160 are formed in the same chamber that performs a continuous process. In addition, forming the second metal line 150 on the first buffer layer 140 is performed such that the second metal line 150 is in contact with the first buffer layer 140, and forming the second buffer layer 160 on the top surface of the second metal line 150 is performed such that the second buffer layer 160 is in contact with the top surface of the second metal line 150.

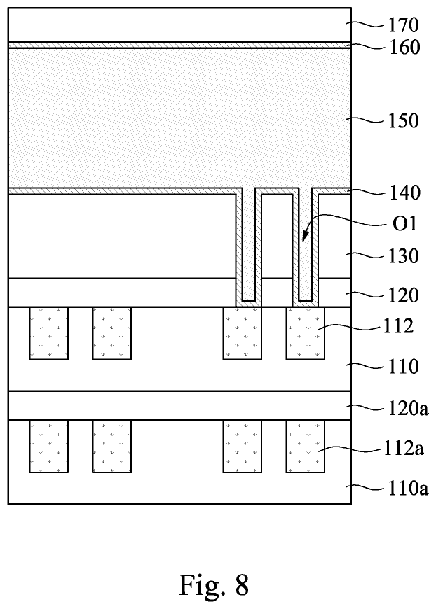

Thereafter, referring to FIG. 8, forming the third dielectric layer 170 is formed on the second buffer layer 160 by deposition. The material of the second buffer layer 160 may be silicon oxynitride (SiON).

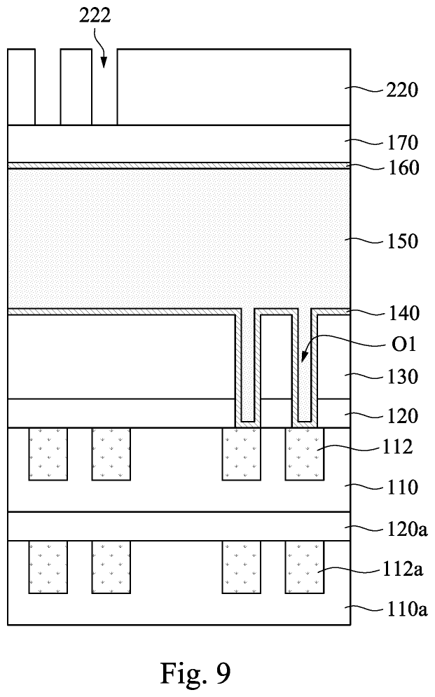

Referring to FIG. 9, after the formation of the second buffer layer 160, a photoresist layer 220 is formed on the top surface of the third dielectric layer 170, wherein the photoresist layer 220 is patterned to have an opening 222 to expose a portion of the top surface of the third dielectric layer 170.

Referring back to FIG. 1, after the formation of the photoresist layer 220 having the opening 222 of FIG. 9, the third dielectric layer 170, the second buffer layer 160, the second metal line 150, the first buffer layer 140, and a top portion of the second dielectric layer 130 can be etched to form a through hole O2, and then the photoresist layer 220 of FIG. 9 can be removed. As a result, the semiconductor structure 100 shown in FIG. 1 can be obtained.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first dielectric layer having a first metal line in a top surface of the first dielectric layer;
a protection layer located on the first dielectric layer;
a second dielectric layer located on the protection layer, wherein the second dielectric layer and the protection layer have a through hole, and the first metal line is below the through hole;
a first buffer layer located on a top surface of the second dielectric layer, a sidewall of the through hole, and a top surface of the first metal line; and
a second metal line located on the first buffer layer and extending into the through hole.

2. The semiconductor structure of claim 1, wherein the second metal line has a bottom portion surrounded by the second dielectric layer and the protection layer.

3. The semiconductor structure of claim 1, wherein the second metal line is integrally formed so as to have no interface therein.

4. The semiconductor structure of claim 1, wherein a material of the second metal line is different from a material of the first metal line.

5. The semiconductor structure of claim 1, wherein a material of the second metal line comprises aluminum, and a thickness of the second metal line above the first buffer layer is in a range from 700 nm to 800 nm.

6. The semiconductor structure of claim 1, wherein a material of the first buffer layer comprises titanium nitride.

7. The semiconductor structure of claim 1, further comprising:
a second buffer layer located on a top surface of the second metal line.

8. The semiconductor structure of claim 7, wherein a material of the second buffer layer is the same as a material of the first buffer layer.

9. The semiconductor structure of claim 7, further comprising:
a third dielectric layer located on the second buffer layer.

10. The semiconductor structure of claim 9, wherein the third dielectric layer, the second buffer layer, the second metal line, the first buffer layer, and a top portion of the second dielectric layer have a through hole.

11. A method of forming a semiconductor structure, comprising:
forming a through hole to expose a first metal line in a top surface of a first dielectric layer, wherein the through hole is located in a second dielectric layer and a protection layer, and the protection layer is located on the first dielectric layer, and the second dielectric layer is located on the protection layer;
forming a first buffer layer on a top surface of the second dielectric layer, a sidewall of the through hole, and a top surface of the first metal line; and
forming a second metal line on the first buffer layer and extending into the through hole.

12. The method of forming the semiconductor structure of claim 11, further comprising:
forming a second buffer layer on a top surface of the second metal line.

13. The method of forming the semiconductor structure of claim 12,
wherein the first buffer layer, the second metal line, and the second buffer layer are formed by sputtering.

14. The method of forming the semiconductor structure of claim 12,
wherein the first buffer layer, the second metal line, and the second buffer layer are formed in the same chamber.

15. The method of forming the semiconductor structure of claim 12, further comprising:
forming a third dielectric layer on the second buffer layer.

16. The method of forming the semiconductor structure of claim 15, further comprising:
etching the third dielectric layer, the second buffer layer, the second metal line, the first buffer layer, and a top portion of the second dielectric layer to form a through hole.

17. The method of forming the semiconductor structure of claim 15, further comprising:
forming a photoresist layer on a top surface of the third dielectric layer, wherein the photoresist layer has an opening to expose a portion of a top surface of the third dielectric layer.

18. The method of forming the semiconductor structure of claim 12, wherein forming the second buffer layer on the top surface of the second metal line is performed such that the second buffer layer is in contact with the top surface of the second metal line.

19. The method of forming the semiconductor structure of claim 11, wherein forming the second metal line on the first buffer layer is performed such that the second metal line is in contact with the first buffer layer.

20. The method of forming the semiconductor structure of claim 11, wherein forming the through hole to expose the first metal line comprises:
forming a photoresist layer on the top surface of the second dielectric layer, wherein the photoresist layer has an opening to expose a portion of the top surface of the second dielectric layer; and
etching the second dielectric layer and the protection layer that are below the opening of the photoresist layer.
